(19) United States
(12) Patent Application Publication
(10) Pub. No.: US 2011/0193211 A1
(43) Pub. Date: Aug. 11, 2011

(54) Surface Preparation of Die for Improved Bonding Strength

(75) Inventors: Arvind Chandrasekaran, San Diego, CA (US); Shiqun Gu, San Diego, CA (US); Urmi Ray, Ramona, CA (US)

(73) Assignee: QUALCOMM INCORPORATED, San Diego, CA (US)

(21) Appl. No.: 12/701,201

(22) Filed: Feb. 5, 2010

(51) Int. Cl. H01L 23/538; H01L 21/56; H01L 21/60

(52) U.S. Cl. 257/686; 438/107; 257/692; 257/E23.135; 257/E23.169; 257/E21.503; 257/E21.509

(57) ABSTRACT

A surface preparation method for improved adhesion in an electronic package system. The method of improving adhesion in the electronic package system includes depositing a passivation layer on a bonding surface and roughening at least a portion of the passivation layer. A coating material is deposited on the passivation layer. The bonding surface can be part of a semiconductor or package substrate. The roughening process can be performed by a chemical or mechanical process. In another embodiment, an electronic package system includes a bonding surface of a semiconductor or package substrate. A passivation layer is deposited on the bonding surface and a portion of the passivation layer is roughened for improved adhesion. A coating material is deposited on the roughened portion of the passivation layer.

### FIELD OF DISCLOSURE

This disclosure relates generally to an electronic package, and in particular to a surface preparation method for improved adhesion in an electronic package system.

### BACKGROUND

In electronic packaging, one or more dies can be coupled together or to an organic substrate to form a package. The reliability of the electronic package can be negatively impacted due to warping and other physical defects. This is particularly true with respect to thin dies and fine pitch flip chip applications in which it can be difficult in the manufacturing process to adhere or couple a die to another die or a package substrate. A thin die, for example, may have a thickness less than 100 μm and a package substrate may have a thickness less than 300 μm.

When a die is coupled to another die or a package substrate, warpage can break apart the die-to-die attachment or die-to-substrate attachment. In some electronic packages, the type of underfill material used between the dies and/or substrate can affect the bonding strength therebetween. In other electronic packages, it is desirable to match or coordinate the coefficient of thermal expansion between two dies, for example, to avoid warpage. However, this can often be difficult to achieve in die-to-substrate systems. Other solutions include using a different type of underfill material that corresponds with or matches the coefficient of thermal expansion of the bonded systems. Matching the coefficient of thermal expansion can be difficult to achieve, however, due to the properties of the different materials.

Therefore, it would be desirable to improve the bonding strength between a die-to-die attachment, a die-to-substrate attachment, or a substrate-to-substrate attachment.

### SUMMARY

For a more complete understanding of the present disclosure, reference is now made to the following detailed description and the accompanying drawings.

In an exemplary embodiment, a method is provided for packaging an integrated circuit. The method includes depositing a first passivation layer on a first bonding surface and roughening at least a portion of the first passivation layer. A first coating material can be deposited on the first passivation, and in some instances, a portion of the first coating material can also be roughened. The roughening process can be a chemical or mechanical process such as plasma bombardment or etching. The first coating material can be hydrophobic or hydrophilic.

The method can also include adhering the first bonding surface to a second bonding surface. A second passivation layer is deposited on the second bonding surface and at least a portion of the second passivation layer is roughened. A second coating material can be deposited on the second passivation layer. In addition, the method can further include depositing an underfill material between the first passivation layer and the second passivation layer. The underfill material can comprise multiple layers such that one layer can be disposed near or in contact with the first passivation layer and a different layer can be disposed near or in contact with the second passivation layer. The underfill material and/or coating material can be selected to achieve the greatest adhesion therebetween.

In another embodiment, an electronic package is provided that includes a first bonding surface of a first semiconductor or package substrate. A first passivation layer is disposed on the first bonding surface and a first coating material is disposed on the first passivation layer. At least a portion of the first passivation layer or first coating material is roughened for improved adhesion. The first coating material can be hydrophilic or hydrophobic. In the case in which the first bonding surface is part of a semiconductor, the thickness of the semiconductor is less than 100 μm. In the case in which the first bonding surface is part of a package substrate, the thickness of the substrate is less than 300 μm.

The electronic package can also include a second bonding surface formed from a semiconductor or package substrate. A second passivation layer can be disposed on the second passivation layer and a second coating material can be disposed on the second passivation layer. A portion of the second passivation layer or second coating material is roughened for improved adhesion. A single or multilayer underfill material can be disposed between the first and second passivation layers.

In a different embodiment, an electronic package system is provided. The system includes a first bonding surface with a first passivation layer disposed thereon and a second bonding surface with a second passivation layer disposed thereon. Also, a coating material is disposed on the first and second passivation layers. A portion of one of the first passivation layer, second passivation layer, and coating material is roughened for improved adhesion. The system can further include a single or multilayer underfill material disposed between the first and second passivation layers. The coating material can be hydrophobic or hydrophilic.

In another exemplary embodiment, an integrated circuit is provided in an electronic package. The integrated circuit comprises a bonding surface of a semiconductor or a package substrate. The circuit further includes a means for protecting the bonding surface of the semiconductor or package substrate and a means for bonding the circuit to another surface. The means for bonding can be deposited on the means for protecting. A portion of the means for protecting or means for bonding is roughened for improved adhesion. The means for bonding can include a hydrophobic or hydrophilic material. In addition, the means for protecting is disposed on the bonding surface.

The above-described embodiments advantageously improve the bonding strength between bonded systems. In particular, thin dies and substrates can be better adhered to one another. Another advantage is that improved surface adhesion can be achieved by following existing manufacturing methods. The passivation layer or coating material can be roughened by plasma bombardment or an etching process. The prior art methods for achieving die-to-die attachment, die-to-substrate attachment, or substrate-to-substrate attachment have been unable to achieve sufficient adhesion between thin dies and substrates. Thus, the present invention overcomes the shortcomings of the prior art and improves the adhesion between thin dies and package substrates.

### BRIEF DESCRIPTION OF THE DRAWINGS

FIG. 1 is a cross-sectional view of an electronic package;

FIG. 2 is a cross-sectional view of a die-to-die coupling in the electronic package of FIG. 1;

FIG. 3 is a cross-sectional view of a portion of a roughened passivation layer along a surface of the die-to-die coupling of FIG. 2;

FIG. 4 is a flow diagram of a surface preparation method for improved adhesion in an electronic package; and

FIG. 5 is a block diagram showing an exemplary wireless communication system in which an electronic package system with improved bonding strength may be advantageously employed.

### DETAILED DESCRIPTION

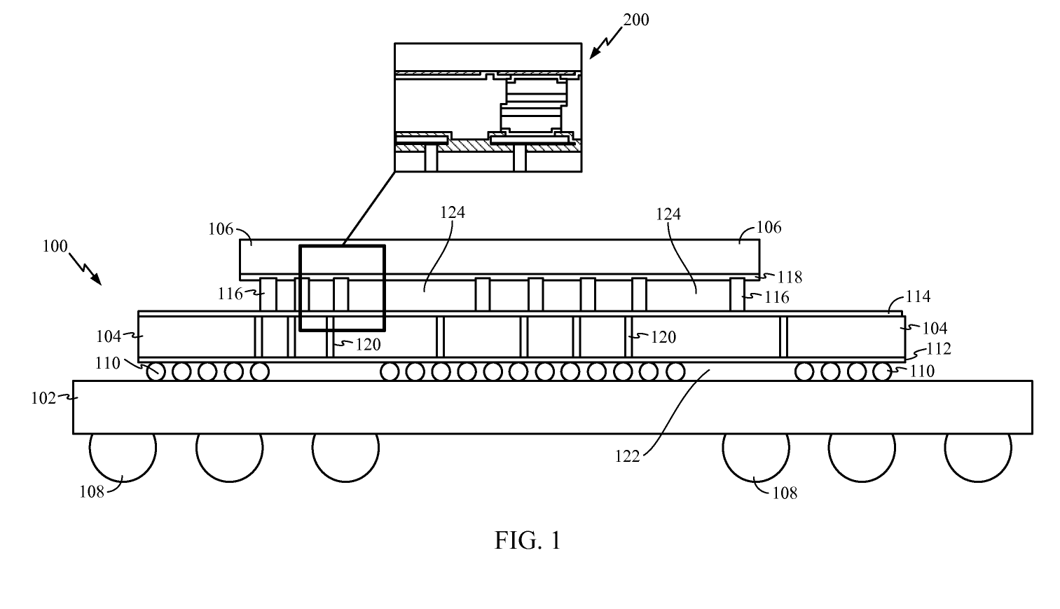

Referring to the exemplary embodiment shown in FIG. 1, an electronic package 100 is provided with an improved bonding strength for preventing or reducing warpage. The package 100 includes a substrate 102, a first die 104 and a second die 106. The first die 104 can be referred to as a lower or Tier 1 die and the second die 106 can be referred to as an upper or Tier 2 die. The substrate 102, which can be made from silicon, glass, or other semiconductor material, can be coupled to a system board (not shown) or another package substrate by a plurality of solder balls 108 or flip chip bumps. Likewise, the first die 104 can be coupled to the substrate 102 by a plurality of bumps 110 (e.g., microbumps, solder bumps, etc.) or any other means for achieving a die-to-substrate attachment. An underfill layer 122 can also be added between the first die 104 and substrate 102 for improved package reliability. Likewise, an underfill material 124 can be disposed between the first and second dies.

Near a front surface of the first die 104, Front-End-of-the-Line (FEOL) and Back-End-of-the-Line (BEOL) sections (shown simplified as a single layer 112) can be formed. The FEOL section can include several top layers for active devices and the BEOL section can include a plurality of metal layers.

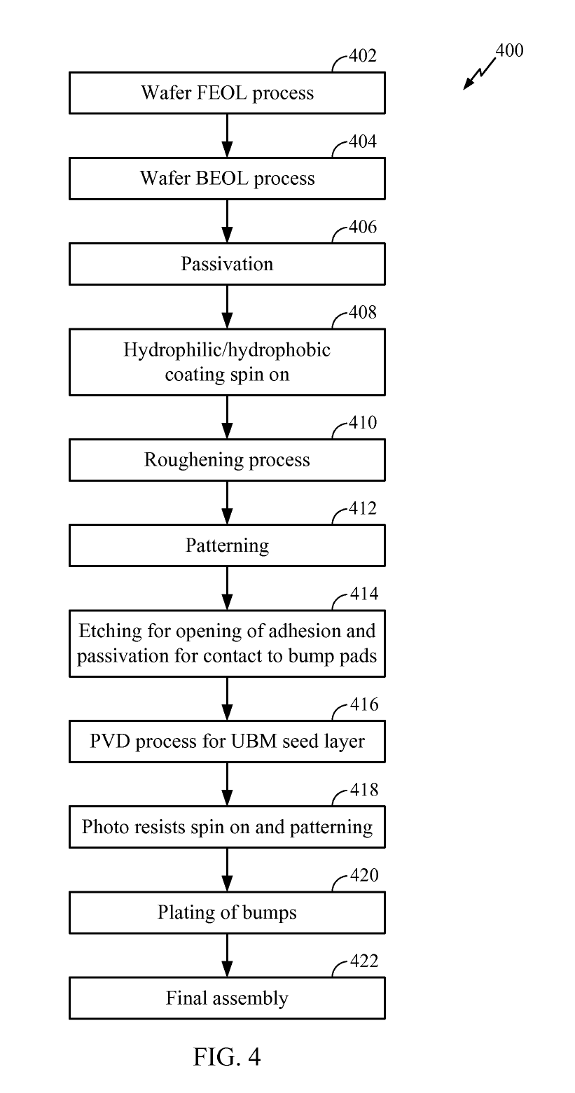

A plurality of through vias 120 can be fabricated in the first die 104. The plurality of vias 120, which can be through-silicon vias, for example, can be formed by a via last process or any other process for forming vias. The plurality of vias 120 can be filled with copper or other conductive material. In addition, one or more metal layers 114 can be disposed at the back surface of the first die 104. The one or more metal layers 114 can be formed of any thermally conductive material such as copper or titanium. At least one of the metal layers can be referred to as a seed layer, which will be described in more detail with respect to FIG. 4.

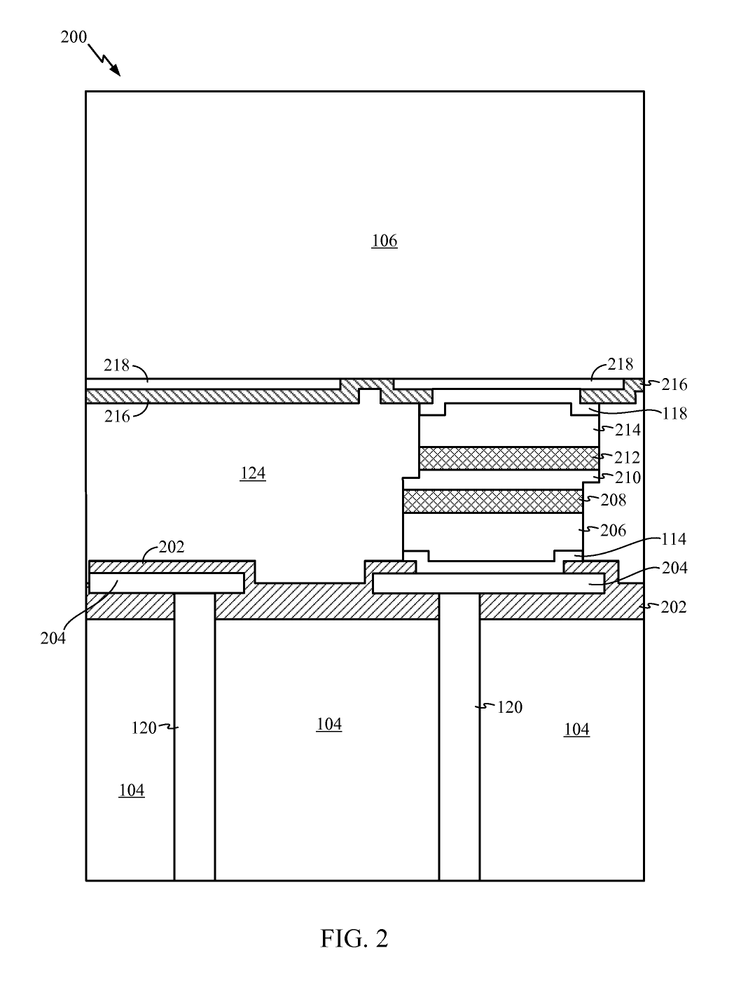

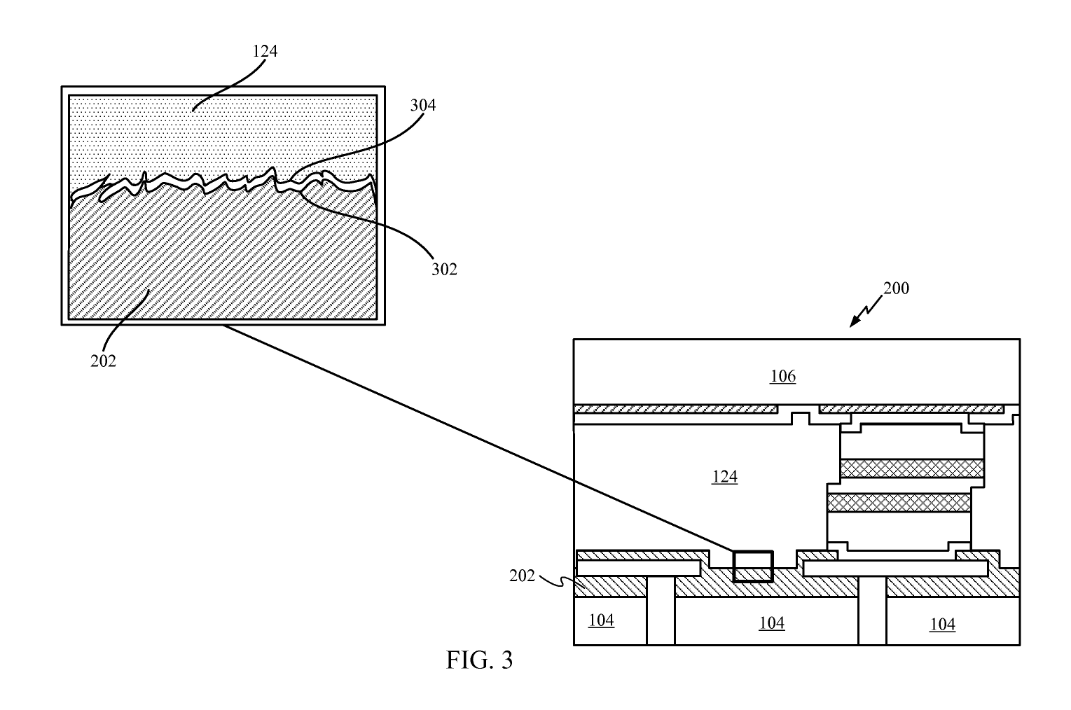

The first die 104 and second die 106 can be coupled together with improved bonding strength. To do so, a microbump formed on the back surface of the first die 104 can be coupled to a microbump formed on the front surface of the second die 106. For purposes of clarification, the back surface of the first die 104 (i.e., the top surface in FIG. 1) and the front surface of the second die 106 (i.e., the bottom surface in FIG. 1) are oriented towards one another. In FIG. 1, the die-to-die coupling 200 is shown as a rectangular shape 116, but in FIGS. 2 and 3, the coupling 200 is illustrated in greater detail.

The second die 106 also can include one or more metal layers 118 which is similar to the one or more metal layers 114 disposed near the back surface of the first die 104. At least one of these metal layers 118 can be a seed layer for forming the microbump, as will be explained in further detail below. The one or more metal layers 118 can be made of a conductive material such as copper or titanium. The first and second dies can be made of silicon or any other die material.

With reference to FIG. 2, the die-to-die coupling 200 is shown in greater detail. As noted above, the first die 104, or Tier 1 die, can be made of silicon and include a plurality of through vias 120 extending therethrough. A first passivation layer 202 can be deposited on the back surface of the first die 104 as shown in FIG. 2. The first passivation layer 202 can be made of silicon nitride, silicon oxide, polyimide, or any other passivation material. The first passivation layer 202 can partially surround a metal layer 204 made of copper or other conductive material. The metal layer 204 is shown being conductively coupled to one of the plurality of vias 120 in the first die 104.

The metal layer 204 is further conductively coupled to another metal layer referred to as the seed layer 114. The seed layer 114, which is part of an underbump metallization (UBM), can be made of copper or titanium. A first microbump 206 is formed from the seed layer 114 and coupled to a second microbump 214 which is formed from the second die 106. The first microbump 206 includes a layer of nickel 208, for example, which can be coupled to another layer of nickel 212 of the second microbump 214. The two layers of nickel 208, 212 are coupled by a solder layer 210.

The second die 106, or Tier 2 die, can also include a second passivation layer 216 similar to the first passivation layer 202 described above. The second passivation layer 216 can surround or contact a second metal layer 218 made of copper or other conductive material. The second metal 218 is also conductively coupled to a seed layer 118 from which the second microbump 214 is formed. The first microbump 206, formed from the first die 104, and second microbump 214, formed from the second die 106, can be made of copper or other conductive material. As noted above, an underfill material 124 is disposed between the first and second dies to improve the reliability of the electronic package and protect interface contacts.

The electronic package 100 is manufactured with an improved bonding strength between at least the first die 104 and second die 106. The first die 104 and package substrate 102 can also be coupled with improved bonding strength in a similar manner. Although not shown, in another embodiment, a substrate-to-substrate attachment can be coupled with improved adhesion as described herein. With reference to FIG. 3, an enhanced view of the interface between the first passivation layer 202 and underfill material 124 is shown. To achieve the improved bonding strength, the surface 302 of the first passivation layer 202 is roughened by a wet or dry process (e.g., chemical or mechanical process). For example, the roughening process can include plasma bombardment, sand blasting, etching, or other known process.

A coating material 304 is deposited on the roughened surface 302 of the first passivation layer 202 to further increase the bonding strength. The coating material 304 can be a hydrophobic material (e.g., epoxy, nitride, etc.) or a hydrophilic material (e.g., polyethylene glycol). The bonding strength can be increased by selecting the coating material 304 which best adheres to the type of underfill material 124 used between the dies. In other words, if the underfill material 124 will adhere better to a hydrophilic material, the bonding strength between the first and second dies is increased when the coating material 304 is hydrophilic. In another embodiment, the coating material 304 can be deposited on the passivation layer and the outer surface of the coating material 304 can be roughened to achieve a desired bonding strength.

In the embodiment of FIG. 2, the underfill material 124 can be a single layer or multilayer underfill. In other words, the underfill material disposed adjacent to the first passivation layer 202 may be different from the underfill material disposed adjacent to the second passivation layer 216. As such, to improve the bonding strength between the first and second dies, the coating material 304 deposited on the first passivation layer 202 may be different from the type of coating material 304 deposited on the second passivation layer 216. As a non-limiting example, the coating material 304 deposited on the first passivation layer 202 may be a hydrophobic material, whereas the coating material 304 deposited on the second passivation layer 216 may be a hydrophilic material. The type of coating material deposited on the passivation layer advantageously corresponds with the underfill material to achieve greater bonding strength between the two dies.

In a different embodiment, a method 400 of fabricating an electronic package with improved adhesion and increased bonding strength is provided. With reference to FIG. 4, the method 400 includes preparing a wafer from which a plurality of dies will be formed. In blocks 402 and 404, for example, preparing the wafer includes Front-End-of-the-Line (FEOL) processing and Back-End-of-the-Line (BEOL) processing. During FEOL processing, which is known, transistors and other devices are formed on the wafer. BEOL processing, which is also known, includes creating metal interconnecting wires to form electrical circuits and isolating the wires with dielectric materials. The wafer is mounted on a carrier such as plastic tape, for example.

Thermal contacts are formed on the wafer at locations where microbumps will be formed. To do so, in block 406, a passivation is deposited on the front or back surface of the wafer where the microbumps will be fabricated. The passivation can serve as a protective layer for the die. For example, the passivation protects the die from debris during manufacturing processes such as bonding. The material can be spin coated, spray coated, chemical vapor deposited (CVD), or physical vapor deposited (PVD) on the die.

Once the passivation is deposited, a coating material is deposited onto the passivation layer in block 408. The coating material can be hydrophilic (e.g., polyethylene glycol) or hydrophobic (e.g., epoxy, nitride, etc.). The type of coating material deposited can depend on the type of underfill material used. Alternatively, the underfill material can include multiple layers such that the type of underfill layer used is selected based on the type of coating material deposited on the passivation layer. The coating material can be spin coated to the passivation layer. Other deposition processes such as molecular vapor deposition (MVD) are possible for depositing the coating material to the passivation layer.

In block 410, a roughening process is performed on at least a portion of the external surface of the passivation layer or coating material. The roughening process can be any dry or wet process, e.g., a chemical or mechanical process. In one embodiment, for example, the roughening process can be achieved by plasma bombardment. In a different embodiment, the roughening process can be achieved by sand blasting. In another embodiment, the roughening process can be performed by etching.

Once the surface of the passivation layer or coating material is roughened, blocks 412 and 414 are performed. To do so, openings are formed in the passivation so that a thermal contact can be fabricated between the underlying wafer and soon-to-be-formed microbump. In other words, the passivation is thermally and electrically insulative such that when openings are formed therein, a conductive path is provided between the die and the microbumps (once formed). If the passivation is photosensitive, the opening in the passivation is formed using photolithography. In this case, a mask is placed on the surface of the wafer on which the microbumps are being fabricated and an ultraviolet or intense light is directed onto the mask. The masked wafer is then placed into a chemical solution, e.g., developer, to wash away or remove the areas exposed to the light. If the passivation is not photosensitive, however, a photosensitive resist material is spin coated or laminated and a similar lithography process is performed.

In block 416, a thin layer of “seed” metal is deposited on the wafer by a physical vapor deposition (PVD) process. In this process, a target consisting of the “seed” metal is bombarded by a high energy source such as a beam of electrons or ions, for example. As such, atoms from the surface of the target are dislodged or vaporized and deposited onto the wafer surface. The seed layer, which is shown, for example, in FIG. 2 as the metal layer 114 fabricated on the back surface of the first die 104 and metal layer 118 fabricated on the front surface of the second die 106, functions as a conductive layer during a plating process and can have a thickness of less than a micron. The seed metal can be, for example, copper or titanium. Other metals can also be used for forming the seed layer.

With reference to block 418, a photo resist is deposited on the wafer by spin coating or a chemical vapor deposit (CVD) process. The wafer is then exposed to a pattern of ultraviolet or intense light, for example. During this process, the cross-section or pattern of the soon-to-be-formed microbump is established. As such, if an area on the wafer is exposed to a circular pattern of intense light through a mask, the microbump being formed in that area will have a circular cross-section. The mask can vary the pattern of ultraviolet or intense light being exposed to the area on the wafer such that microbumps can have any shaped cross-section. This is especially important if the available area on the die has a specific shape such that the microbump(s) formed in this area can be maximized to achieve desired adhesion between dies and/or substrates (this process is similar when attaching a die to a package substrate or a package substrate to another package substrate). For example, if the available area on the die is substantially annular, the masked pattern of ultraviolet or intense light can be substantially annular to form one or more microbumps having a specific cross-section for occupying the substantially annular area on the die.

In block 420, the photo resist is dipped into an electrolytic bath with both current and time being controlled. Copper or any other thermally conductive electrolytic metal can be deposited electrolytically in those areas which have an exposed seed layer. As such, one or more microbumps is integrally formed with the wafer. In the case of a single microbump being formed, the size of the microbump can be varied by changing the amount of time the photo resist is dipped into the electrolytic bath.

Also in block 420, the photo resist can be stripped. One way to strip the photo resist is by using plasma bombardment in a dry process. Alternatively, in a wet process, the remaining resist can be dissolved by chemically altering the resist such that it no longer adheres to the wafer. In other embodiments, the resist can be peeled off the wafer. In an embodiment in which the photo resist is thicker, the plasma bombardment or peeling methods are preferred. The seed layer can now be etched away. In addition, a small amount of material is removed through plasma bombardment.

Once the one or more microbumps is formed on the front or back surface of the wafer, in block 422, the wafer is cut or diced into a plurality of die. A single die can be integrated into an electrical package, for example, by attaching the die to a substrate. A second die can be mounted onto a first die (e.g., the embodiment in FIG. 2) and additional dies can be stacked to form a multi-die package. Once integrated into a package, package back-end assembly can be completed to form the electrical package.

A similar process can be carried out for coupling a die to a substrate or a substrate to another substrate.

The bonding strength of the electronic package is increased by roughening the surface of either the passivation layer or coating material in block 410. In particular, in a die-to-die configuration, there is improved adhesion between the dies and the underfill or epoxy material. In addition, the coating material further increases the bonding strength between the die (or substrate) and underfill material when the type of coating material (e.g., hydrophilic or hydrophobic) is selected based on the type of underfill material or vice versa.

The above-described embodiment is particularly advantageous when used for bonding a thin die or fine pitch flip chip to another die or substrate. A thin die, for example, can have a thickness less than 100 μm and a package substrate can have a thickness less than 300 μm. Known solutions including those described above in the Background have been unable to achieve desirable adhesion between such thin dies and package substrates. However, by performing the surface preparation method disclosed above, the bonding strength can be increased to a desirable level between thin dies and/or substrates.

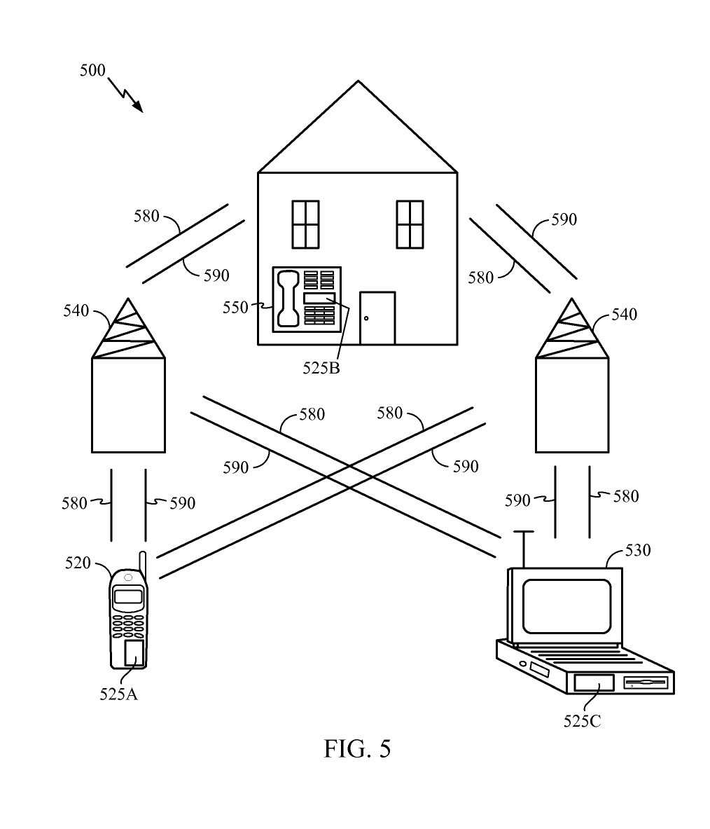

FIG. 5 shows an exemplary wireless communication system 500 in which an embodiment of an electronic package system with improved bonding strength may be advantageously employed. For purposes of illustration, FIG. 5 shows three remote units 520, 530, and 550 and two base stations 540. It should be recognized that typical wireless communication systems may have many more remote units and base stations. Any of remote units 520, 530, and 550 may include an electronic package system with improved bonding strength such as disclosed herein. FIG. 5 shows forward link signals 580 from the base stations 540 and the remote units 520, 530, and 550 and reverse link signals 590 from the remote units 520, 530, and 550 to base stations 540.

In FIG. 5, remote unit 520 is shown as a mobile telephone, remote unit 530 is shown as a portable computer, and remote unit 550 is shown as a fixed location remote unit in a wireless local loop system. For example, the remote units may be cell phones, hand-held personal communication systems (PCS) units, portable data units such as personal data assistants, music and/or video players, entertainment units, navigation devices, or fixed location data units such as meter reading equipment. Although FIG. 5 illustrates certain exemplary remote units that may include an electronic package system with improved bonding strength as disclosed herein, the package substrate is not limited to these exemplary illustrated units. Embodiments may be suitably employed in any electronic device in which an electronic package system with improved bonding strength is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for packaging an integrated circuit, comprising:
depositing a first passivation layer on a first bonding surface;
roughening at least a portion of the first passivation layer; and
depositing a first coating material on the first passivation layer.

2. The method of claim 1, further comprising roughening at least a portion of the first coating material.

3. The method of claim 1, wherein the roughening at least a portion is a chemical or mechanical process.

4. The method of claim 3, wherein the roughening at least a portion comprises plasma bombardment or an etching process.

5. The method of claim 1, wherein the first coating material is hydrophobic or hydrophilic.

6. The method of claim 1, further comprising adhering the first bonding surface to a second bonding surface.

7. The method of claim 6, further comprising:
depositing a second passivation layer on the second bonding surface;
roughening at least a portion of the second passivation layer; and
depositing a second coating material on the second passivation layer.

8. The method of claim 7, further comprising depositing an underfill material between the first passivation layer and second passivation layer.

9. The method of claim 8, wherein the depositing an underfill material comprises depositing a multilayer underfill material between the first passivation layer and the second passivation layer.

10. The method of claim 8, further comprising selecting the underfill material and the first and second coating materials to promote adhesion therebetween.

11. The method of claim 6, wherein the first and second bonding surfaces are formed from a semiconductor or package substrate.

12. The method of claim 11, wherein when the first or second bonding surface is formed from a semiconductor, the semiconductor has a thickness less than 100 μm.

13. The method of claim 11, wherein when the first or second bonding surface is formed from a package substrate, the package substrate has a thickness less than 300 μm.

14. The method of claim 1 incorporated into a device selected from a group consisting of a music player, a video player, an entertainment unit, a navigation device, a communications device, a personal digital assistant (PDA), a fixed location data unit, and a computer.

15. An electronic package, comprising:
a first bonding surface of a first semiconductor or package substrate;
a first passivation layer disposed on the first bonding surface; and
a first coating material disposed on the first passivation layer;
wherein, at least a portion of the first passivation layer or the first coating material is roughened for improved adhesion.

16. The electronic package of claim 15, wherein the first coating material is hydrophilic or hydrophobic.

17. The electronic package of claim 15, wherein when the first bonding surface is part of a semiconductor, the thickness of the semiconductor is less than 100 μm.

18. The electronic package of claim 15, wherein when the first bonding surface is part of a package substrate, the thickness of the package substrate is less than 300 μm.

19. The electronic package of claim 15, further comprising:
a second bonding surface formed from a second semiconductor or package substrate;
a second passivation layer disposed on the second bonding surface; and
a second coating material disposed on the second passivation layer;
wherein, at least a portion of the second passivation layer or second coating material is roughened for improved adhesion.

20. The electronic package of claim 19, further comprising an underfill material disposed between the first passivation layer and the second passivation layer.

21. The electronic package of claim 20, wherein the underfill material comprises multiple layers of underfill material.

22. The electronic package of claim 21, wherein the underfill material contacting the first passivation layer is different from the underfill material contacting the second passivation layer.

23. The electronic package of claim 15 incorporated into a device selected from a group consisting of a music player, a video player, an entertainment unit, a navigation device, a communications device, a personal digital assistant (PDA), a fixed location data unit, and a computer.

24. An electronic package system, comprising:
a first bonding surface with a first passivation layer disposed thereon;
a second bonding surface with a second passivation layer disposed thereon;
a coating material disposed on the first passivation layer and the second passivation layer;
wherein, at least a portion of one of the first passivation layer, second passivation layer, or coating material is roughened.

25. The electronic package system of claim 24, further comprising an underfill material disposed between the first and second passivation layers.

26. The electronic package system of claim 25, wherein the underfill material comprises multiple layers of underfill material.

27. The electronic package system of claim 24, wherein the coating material disposed on the first passivation layer is different from the coating material disposed on the second passivation layer.

28. The electronic package system of claim 24, wherein the coating material is hydrophobic or hydrophilic.

29. The electronic package system of claim 24, wherein the first bonding surface is part of a semiconductor or package substrate.

30. The electronic package system of claim 29, wherein the second bonding surface is part of a semiconductor or package substrate.

31. The electronic package system of claim 30, wherein if one of the first or second bonding surface is part of a semiconductor, the thickness of the semiconductor is less than 100 μm.

32. The electronic package system of claim 30, wherein if one of the first or second bonding surface is part of a package substrate, the thickness of the package substrate is less than 300 μm.

33. The electronic package system of claim 24, wherein the portion of one of the first passivation layer or second passivation layer is roughened by a chemical or mechanical process.

34. The electronic package system of claim 33, wherein the process comprises plasma bombardment or etching.

35. The electronic package system of claim 24 incorporated into a device selected from a group consisting of a music player, a video player, an entertainment unit, a navigation device, a communications device, a personal digital assistant (PDA), a fixed location data unit, and a computer.

36. An integrated circuit in an electronic package, comprising:
a bonding surface of a semiconductor or package substrate;
a means for protecting the bonding surface of the semiconductor or package substrate;
a means for bonding the circuit to another surface, the means for bonding being deposited on the means for protecting;
wherein, at least a portion of the means for protecting or the means for bonding is roughened.

37. The integrated circuit of claim 36, wherein the means for bonding comprises a hydrophilic or hydrophobic material.

38. The integrated circuit of claim 36, wherein the means for protecting is disposed on the bonding surface.

39. The integrated circuit of claim 36 incorporated into a device selected from a group consisting of a music player, a video player, an entertainment unit, a navigation device, a communications device, a personal digital assistant (PDA), a fixed location data unit, and a computer.
